(19) United States
(12) Patent Application Publication
(10) Pub. No.: US 2025/0324701 A1
(43) Pub. Date: Oct. 16, 2025

(54) BACKSIDE GATE CONTACT, BACKSIDE GATE ETCH STOP LAYER, AND METHODS OF FORMING SAME

(71) Applicant: Taiwan Semiconductor Manufacturing Co., Ltd., Hsinchu (TW)

(72) Inventors: Wei-De Ho, Hsinchu (TW); Szuya Liao, Zhubei (TW)

(21) Appl. No.: 19/247,254

(22) Filed: Jun. 24, 2025

Related U.S. Application Data
(63) Continuation of application No. 18/463,596, filed on Sep. 8, 2023.
(60) Provisional application No. 63/487,031, filed on Feb. 27, 2023.

(51) Int. Cl. H10D 64/01; H10D 30/67; H10D 62/10; H10D 84/01; H10D 84/03; H10D 84/83

(52) U.S. Cl. CPC H10D 64/017; H10D 30/6735; H10D 62/115; H10D 62/118; H10D 64/018; H10D 84/0128; H10D 84/0149; H10D 84/038; H10D 84/83

(57) ABSTRACT

A semiconductor device includes a backside gate etch stop layer (ESL) on a backside of a first gate stack, wherein a plurality of first nanostructures overlaps the backside gate ESL. The backside gate ESL may comprise a high-k dielectric material. The semiconductor device further includes the plurality of first nanostructures extending between first source/drain regions and a plurality of second nanostructures over the plurality of first nanostructures and extending between second source/drain regions. A first gate stack is disposed around the plurality of first nanostructures, and a second gate stack over the first gate stack is disposed around the plurality of second nanostructures. A backside gate contact extends through the backside gate ESL to be electrically coupled to the first gate stack.

### PRIORITY CLAIM AND CROSS-REFERENCE

This application is a continuation of U.S. application Ser. No. 18/463,596, filed on Sep. 8, 2023, which claims the benefit of the following provisionally filed U.S. Patent application: Application No. 63/487,031, filed on Feb. 27, 2023, and entitled “BVG on OD Integration for Performance Improvement,” which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example stacking transistors in accordance with some embodiments.

FIGS. 2A, 2B, 3, 4, 5, 6, 7, 8A, 8B, 9, 10, 11, 12, 13, 14, 15, 16A, and 16B are views of intermediate stages in the manufacturing of a stacking transistor in accordance with some embodiments.

FIGS. 17, 18, 19, 20, 21, 22, 23, 24A, and 24B are views of intermediate stages in the manufacturing of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor, such as a CFET, and the method of forming the same are provided. In various embodiments, the stacking transistor includes two vertically stacked transistors, and a gate etch stop layer (ESL) is formed on the backside of a lower gate stack of the stacking transistor. Channel regions of the stacking transistor may overlap the gate ESL. In some embodiments, the gate ESL may be made of a high-k dielectric material having a k-value of at least 15, for example.

The gate ESL allows for backside gate contacts to be formed to the lower gate stack at a location where the backside gate contacts are overlapped by the channel regions of the stacking transistor without damaging the channel regions during the backside gate contact formation process. As a result, the locations overlapped by channel regions do not need to be avoided when forming the backside gate contacts, allowing for improved routing flexibility. Further, because channel regions are able to directly overlap the backside gate contacts, channel regions can be designed and fabricated with larger widths for improved device speed. For example, between 14.4% to 19% device speed improvements have been observed in embodiment devices by increasing the widths of the channel regions. As a result, various embodiments allow for improved process integration, increased routing flexibility, and increased device performance.

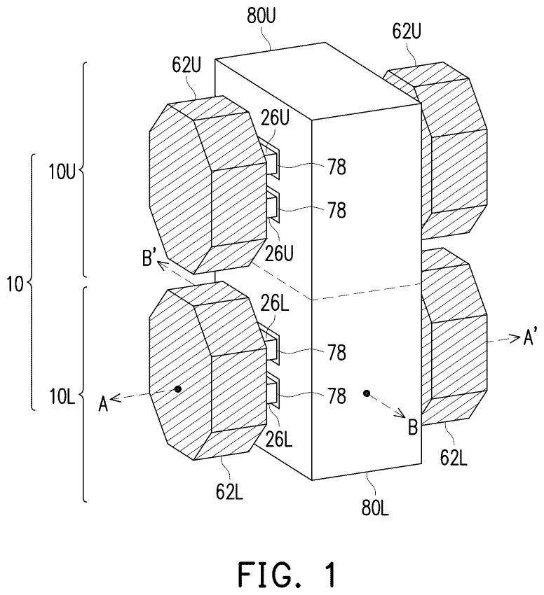

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of the stacking transistor 10 and in a direction of, for example, a current flow between the source/drain regions 62 of the stacking transistor 10. Cross-section B-B′ is a vertical cross-section that is perpendicular to cross-section A-A′ and along a longitudinal axis of a gate electrodes 80 of the stacking transistor 10.

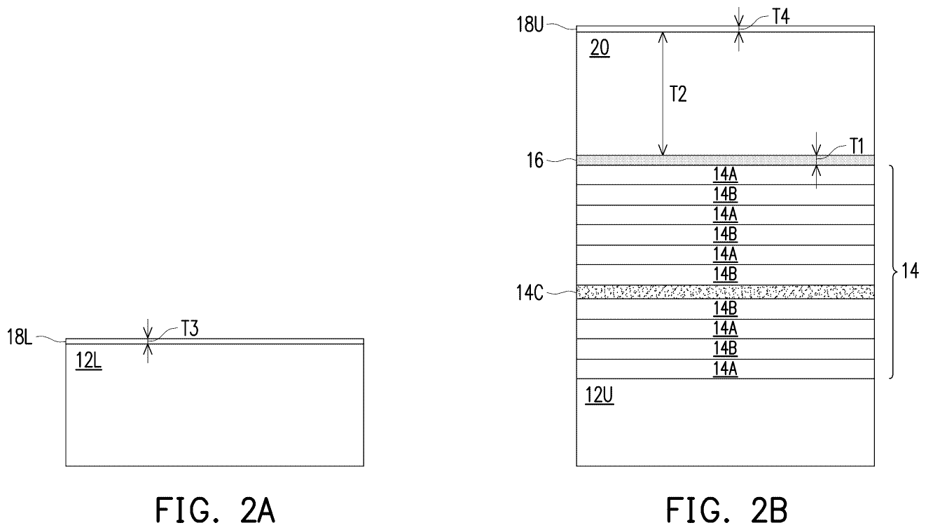

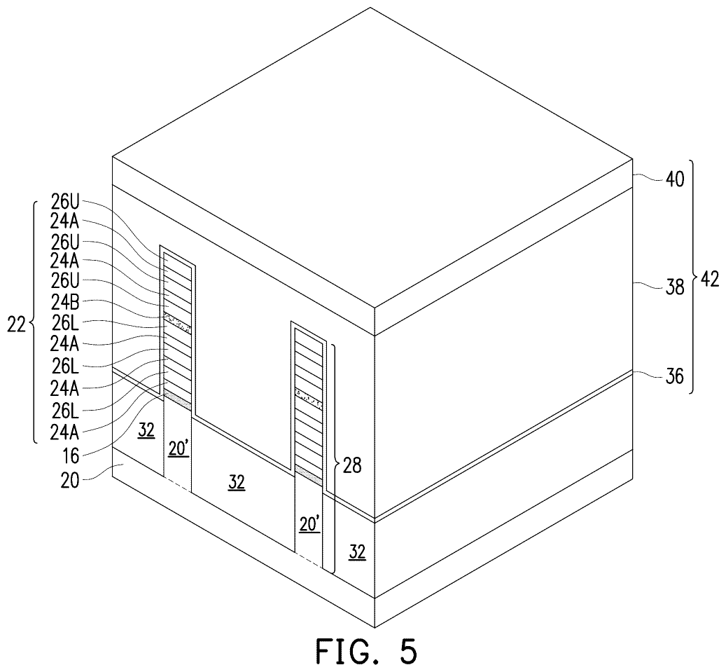

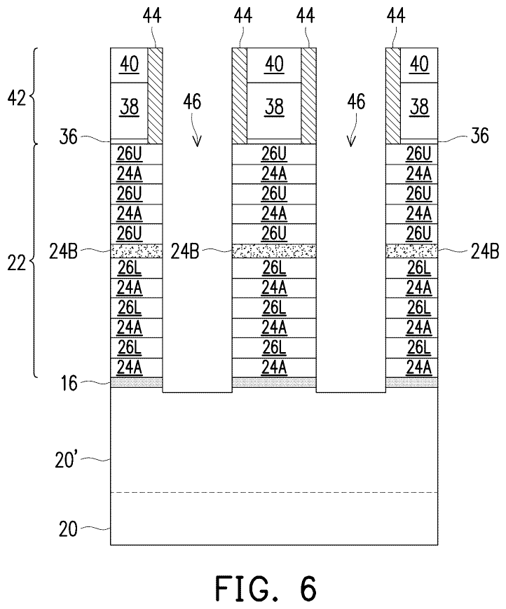

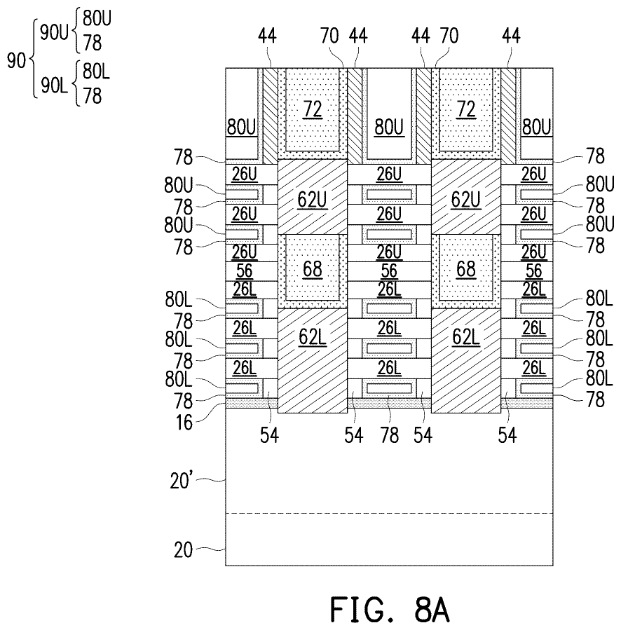

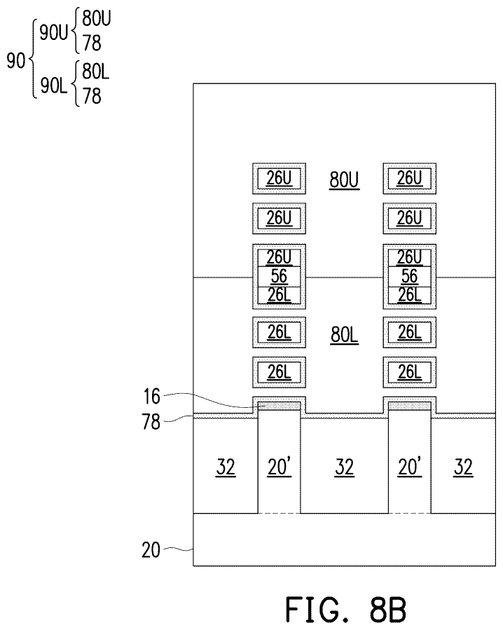

FIGS. 2A through 16B illustrate the cross-sectional views of intermediate stages in the formation of stacking transistors (as schematically represented in FIG. 1) in accordance with some embodiments. FIGS. 2A, 2B, 3, and 4 illustrate general cross-sectional views. FIG. 5 illustrates a perspective view similar to FIG. 1. FIGS. 6, 7, 8A, 9, and 16A illustrate cross-sectional views along a similar cross-section as reference cross-section A-A′ in FIG. 1. FIGS. 8B, 11, 12, 13, 14, 15, and 16B illustrate cross-sectional views along a similar cross-section as reference cross-section B-B′ in FIG. 1.

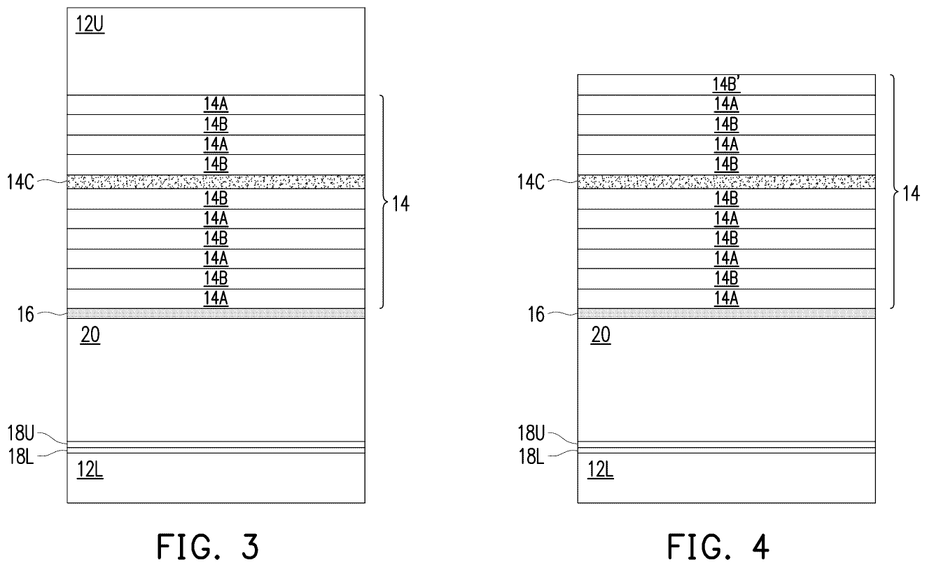

In FIGS. 2A and 2B, two substrates 12L and 12U are separately provided. FIG. 2A illustrates a substrate 12L, and FIG. 2B illustrates a substrate 12U. In subsequently processes, the substrate 12U may be bonded over the substrate 12L (see FIG. 3). As such, the substrate 12L may be referred to as a lower substrate 12L, and the substrate 12U may also be referred to as an upper substrate 12U. Each of the substrates 12L and 12U may be a semiconductor substrate, such as a bulk semiconductor, a semiconductor-on-insulator (SOI) substrate, or the like, which may be doped (e.g., with a p-type or an n-type dopant) or undoped. The substrates 12L and 12U may each be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrates 12L and 12U may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In some embodiments, each of the substrates 12L and 12U may include an embedded CMP stop layer (not separately illustrated), such as a layer of silicon germanium embedded (e.g., sandwiched) between silicon material layers.

A multi-layer stack 14 is formed over the upper substrate 12U. The multi-layer stack 14 includes alternating dummy semiconductor layers 14A, 14C and semiconductor layers 14B. As subsequently described in greater detail, the dummy semiconductor layers 14A and 14C will be removed, and the semiconductor layers 14B will be patterned to form channel regions of a stacking transistor. For example, the semiconductor layers 14B disposed above the dummy semiconductor layer 14C may be patterned to form channel regions of a first transistor of the stacking transistor, and semiconductor layers 14B disposed below the dummy semiconductor layer 14C may be patterned to form channel regions of a second transistor of the stacking transistor.

The dummy semiconductor layers 14A and 14C are formed of a first semiconductor material selected from the candidate semiconductor materials of the substrates 12L and 12U. The semiconductor layers 14B are formed of one or more second semiconductor material(s) also selected from the candidate semiconductor materials of the substrates 12L and 12U. The semiconductor layers 14B above the dummy semiconductor layer 14C may be formed of the same semiconductor material or may be formed of different semiconductor materials than the semiconductor layers 14B below the dummy semiconductor layer 14C. In some embodiments, each of the semiconductor layers 14B is formed of a semiconductor material suitable for p-type devices and n-type devices, such as silicon. In some embodiments, the semiconductor layers 14B above the dummy semiconductor layer 14C are formed of a semiconductor material suitable for p- type devices, such as germanium or silicon germanium, and the semiconductor layers 14B below the dummy semiconductor layer 14C are formed of a semiconductor material suitable for n-type devices, such as silicon or carbon-doped silicon. In some embodiments, the semiconductor layers 14B below the dummy semiconductor layer 14C are formed of a semiconductor material suitable for p-type devices, such as germanium or silicon germanium, and the semiconductor layers 14B above the dummy semiconductor layer 14C are formed of a semiconductor material suitable for n-type devices, such as silicon or carbon-doped silicon.

The semiconductor material(s) of the semiconductor layers 14B are different from and have a high etching selectivity to the semiconductor materials of the dummy semiconductor layers 14A and 14C. As such, the materials of the dummy semiconductor layers 14A and 14C may be removed at a faster rate than the material of the semiconductor layers 14B in subsequent processing. Further, the semiconductor material of the dummy semiconductor layer 14C has a high etching selectivity to the semiconductor material(s) of the dummy semiconductor layers 14A. As such, the material of the dummy semiconductor layer 14C may be selectively removed in subsequent process steps without completely removing materials of the dummy semiconductor layer 14A. In some embodiments, dummy semiconductor layers 14A are formed of silicon germanium, the semiconductor layers 14B are formed of silicon, and the dummy semiconductor 14C may be formed of germanium or silicon germanium with a higher germanium atomic percentage than the dummy semiconductor layers 14A.

The multi-layer stack 14 is illustrated as including a specific number of the dummy semiconductor layers 14A, 14C and the semiconductor layers 14B. It should be appreciated that the multi-layer stack 14 may include any number of the dummy semiconductor layers 14A, 14C and/or the semiconductor layers 14B. Each layer of the multi-layer stack 14 may be grown by a process such as vapor phase epitaxy (VPE) or molecular beam epitaxy (MBE), deposited by a process such as chemical vapor deposition (CVD) or atomic layer deposition (ALD), or the like.

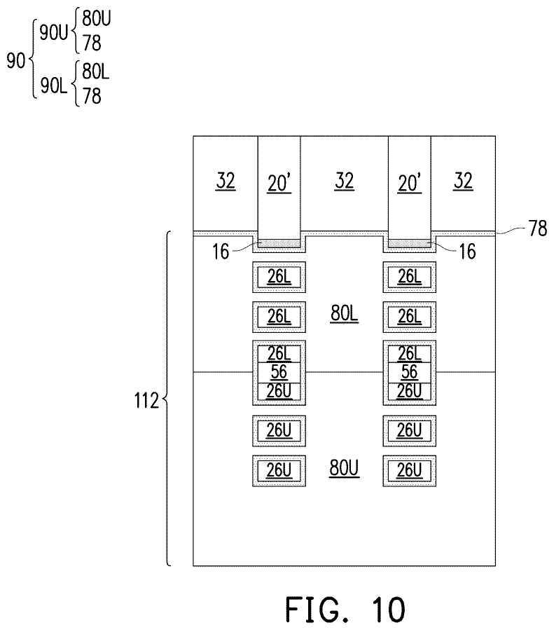

Still referring to FIG. 2B, an ESL 16 is deposited over the multi-layer stack 14. In subsequent process steps, the ESL 16 may be used to control an etching process for forming a backside gate contact in a region that overlaps channel regions of the stacking transistor (see FIGS. 10 through 16B). As such, the ESL 16 may also be referred to as a gate ESL or a backside gate ESL. The ESL 16 may be formed of a material that provides etch selectivity with respect to the material of the channel regions (e.g., the material of the semiconductor layers 14B) and a material of the subsequently formed gate stacks. For example, the ESL 16 may comprise a high-k dielectric material, such as hafnium oxide, or the like. In some embodiments, a k-value of the ESL 16 is at least 15, and the ESL 16 has a thickness Ti that is in a range of 3 nm to 6 nm. It has been observed that when the ESL 16 has a k-value and thickness in the above ranges, it is suitable for forming a backside gate contact. For example, when the ESL 16 has a thickness less than 3 nm, the backside gate contact formation may unacceptably damage other features of the device (e.g., the gate stack and/or channel regions) and cause leakage concerns. When the ESL 16 has a thickness greater than 6 nm, it may be unduly difficult and/or lengthy to etch through, complicating the manufacturing process. The ESL 16 may be deposited by any suitable process, such as CVD, ALD, or the like.

A semiconductor layer 20 is deposited over the ESL 16. In some embodiments, the semiconductor layer 20 is made of a material that can be subsequently patterned into semiconductor fins, such as amorphous silicon. A thickness T2 of the semiconductor layer 20 may also be selected so that it is sufficiently thick to subsequently pattern semiconductor strips (also referred to as semiconductor fins) in the semiconductor layer 20. For example, the thickness T2 of the semiconductor layer 20 may be at least 100 nm. The semiconductor layer 20 may be deposited by any suitable process, such as CVD, ALD, or the like.

As further illustrated by FIGS. 2A and 2B, bonding layers 18L and 18U are deposited over the substrates 12L and 12U, respectively. Specifically, the bonding layer 18L may be deposited over the substrate 12L, and the bonding layer 18U may be deposited over the semiconductor layer 20. The bonding layers 18L and 18U may be deposited by any suitable process, such as physical vapor deposition (PVD), CVD, ALD, or the like. The bonding layers 18L and 18U may facilitate the bonding of the lower substrate 12L to the upper substrate 12U in subsequent processes (see FIG. 3). The bonding layers 18L and 18U may each comprise an insulating material that is suitable for a subsequent dielectric-to-dielectric bonding process. Example materials for the bonding layers 18L and 18U include silicon oxide (e.g., SiO2), silicon nitride, silicon oxynitride, silicon carbonitride, silicon oxycarbonitride, or the like. A material composition of the bonding layer 18L may be the same or different than a material composition of the bonding layer 18U. In some embodiments, a thickness T3 of the bonding layer 18L and a thickness T4 of the bonding layer 18U may each be at least 50 nm to provide a sufficiently thick bonding layer for subsequent bonding processes. The thicknesses T3 and T4 may be equal or different from each other.

In FIG. 3, the upper substrate 12U, having the multi-layer stack 14, the ESL 16, and the semiconductor layer 20 disposed thereon, is flipped over and bonded to the lower substrate 12L. The bonded structure includes the lower substrate 12L; bonding layers 18L and 18U over the lower substrate 12L; the semiconductor layer 20 over the bonding layers 18L and 18U, the ESL 16 over the semiconductor layer 20; the multi-layer stack 14 over the ESL 16, and the upper substrate 12U over the multi-layer stack 14. Specifically, the bonding layers 18L and 18U may be bonded together using a suitable technique, such as dielectric-to-dielectric bonding, or the like. After bonding, the lower bonding layer 18L and the upper bonding layer 18U may be collectively referred to as a bonded layer 18. The bonded layer 18 may or may not have an interface disposed therein where the bonding layer 18L meets the bonding layer 18U.

In some embodiments, the dielectric-to-dielectric bonding process includes applying a surface treatment to one or more of the bonding layers 18L and 18U to form hydroxyl (OH) groups at exposed surfaces of the bonding layers 18L and 18U. The surface treatment may include a plasma treatment, such as a nitrogen (N₂) plasma treatment. After the plasma treatment, the surface treatment may further include a cleaning process that may be applied to one or more of the bonding layers 18L and 18U. The bonding layer 18U may then be placed over and aligned to the bonding layer 18L. The two bonding layers 18L and 18U are then pressed against each other to initiate a pre-bonding of the upper substrate 12U to the lower substrate 12L. The pre-bonding be performed at room temperature (e.g., in a range of 20° C. to 28° C.). After the pre-bonding, an annealing process may be applied by, for example, heating the substrates 12L and 12U to a temperature of in a range of 300° C. to 500° C. The annealing process triggers the formation of covalent bonds between the bonding layers 18L and 18U.

In FIG. 4, a thinning process is applied to reduce a thickness of the upper substrate 12U to a desired thickness, forming a semiconductor layer 14B′. The thinning process may include a grinding process, a chemical mechanical polish (CMP), an etch back process, combination thereof, or the like. The thinning process may reduce a thickness of the upper substrate 12U to match a thickness of each of the semiconductor layers 14B. In subsequent process steps, the semiconductor layer 14B′ resulting from the thinned upper substrate 12U, may be patterned to provide a nanostructure (e.g., channel region) for an upper nanostructure-FETs of the stacking transistors, and the semiconductor layer 14B′ may be referred to as a component of the multi-layer stack 14.

In FIG. 5, the multi-layer stack 14, the ESL 16, and the semiconductor layer 20 are patterned to form semiconductor strips 28 extending upwards from the semiconductor layer 20. In FIG. 5 and subsequent figures, layers underlying the semiconductor layer 20 (e.g., the bonded layer 18 and the lower substrate 12L) are omitted for ease of illustration only. It should be understood that unless otherwise indicated, these layers remain below the semiconductor layer 20. Each of semiconductor strips 28 includes semiconductor strip 20′ (patterned portions of the semiconductor layer 20), patterned portions of the ESL 16, and a multi-layer stack 22. The stacked component of the multi-layers stack 22 is referred to as nanostructures hereinafter. Specifically, each multi-layer stack 22 includes dummy nanostructures 24A patterned from a material of the dummy semiconductor layer 14A; a dummy nanostructure 24B patterned from a material of the dummy semiconductor layer 14C; lower semiconductor nanostructures 26L patterned from semiconductor layers 14B under the dummy semiconductor layer 14C (see FIG. 4); and upper semiconductor nanostructures 26U patterned from semiconductor layers 14B/14B′ over the dummy semiconductor layer 14C (see FIG. 4). Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The lower semiconductor nanostructures 26L will provide channel regions for lower nanostructure-FETs of the stacking transistors. The upper semiconductor nanostructures 26U will provide channel regions for upper nanostructure-FETs of the stacking transistors. The semiconductor nanostructures 26 that are immediately above/below (e.g., in contact with) the dummy nanostructures 24B may be used for isolation and may or may not act as channel regions for the stacking transistors. The dummy nanostructures 24B will be subsequently replaced with isolation structures, which may define boundaries of the lower nanostructure-FETs and the upper nanostructure-FETs.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor layer 20. The etching may be performed by any acceptable etch process, such as a Reactive Ion Etch (RIE), Neutral Beam Etch (NBE), the like, or a combination thereof. The etching may be anisotropic.

As also illustrated by FIG. 5, shallow trench isolation STI regions 32 are formed over the semiconductor layer 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22 and the ESL 16) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 6, gate spacers 44 are formed along sidewalls of the dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22, through the ESL 16, and into the semiconductor strips 20′. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

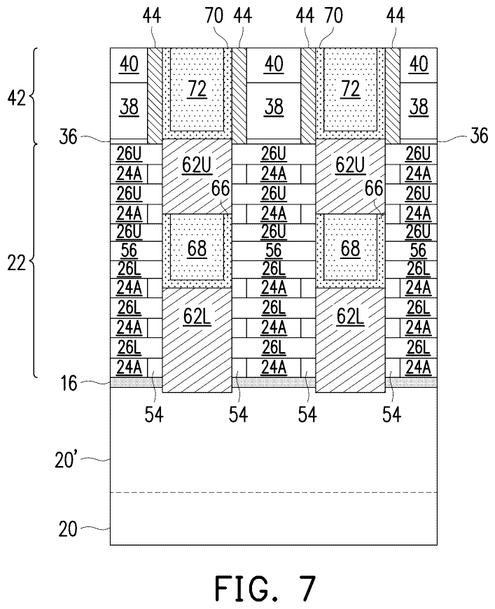

In FIG. 7, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 wrap around sidewalls of the semiconductor nanostructures 26 (see FIG. 5), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 56A, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 24A (thus forming the inner spacers 54) and has portions remaining in between the upper and lower semiconductor nanostructures 26U and 26L (thus forming the dielectric isolation layers 56).

As also illustrated by FIG. 7, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, the upper semiconductor nanostructures 26U may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first interlayer dielectric ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. In embodiments where the stacking transistors are CFETs, the conductivity type of the upper epitaxial source/drain regions 62U may be opposite the conductivity type of the lower epitaxial source/drain regions 62L. For example, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

FIGS. 8A and 8B illustrate different cross-sections of a replacement gate process to replace the dummy gate stacks 42 and the dummy nanostructures 24A with gate stacks 90. FIG. 8A illustrates a cross-sectional view along reference line A-A′ of FIG. 1; and FIG. 8B illustrates a cross-sectional view along reference line B-B′ of FIG. 1. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation layers 56, the inner spacers 54, and the ESL 16. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor strips 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) and recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1 and FIG. 8B). The lower gate structures 90L may also extend along sidewalls and/or a top surface of the ESL 16 and along sidewalls of the semiconductor strips 20′ (see FIG. 8B).

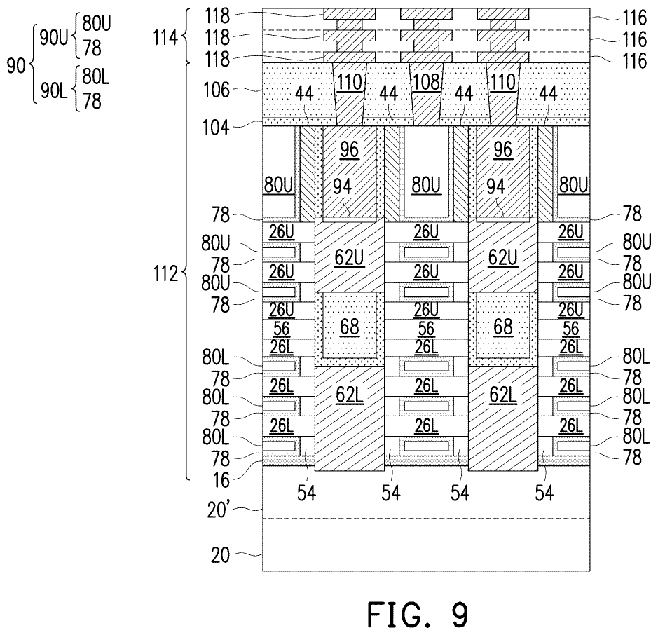

In FIG. 9, metal-semiconductor alloy regions 94 and source/drain contacts 96 are formed through the second ILD 72 to electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. As will be explained in greater detail below, contacts to the lower gate stacks 90L and the lower source/drain regions 62L may be made through a backside of the device layer 112 (e.g., a side opposite to the front-side interconnect structure 114).

FIGS. 10 through 16B illustrate cross-sectional views of intermediate steps of forming backside gate contacts and source/drain contacts according to the lower gate stacks 90L and the lower source/drain regions 62L in accordance with some embodiments. In FIGS. 10 through 16A, features on the front-side of the device layer 112 beyond the upper gate stack 80U are omitted for ease of illustration, but it should be understood that the ESL 104, the third ILD 106, and the front-side interconnect structure 114 are disposed below the upper gate stack 80U in the cross-sections illustrated by FIGS. 10 through 16A. Referring to FIG. 10, an orientation of the device may be flipped. For example, a carrier substrate (not explicitly illustrated) may be bonded to the front-side interconnect structure 114 by dielectric-to-dielectric bonding, and the device may be flipped to expose a backside of the device layer 112 (the side of the device layer 112 opposite to the front-side interconnect structure 114). Then, a planarization process may be performed on the backside of the device layer 112. In some embodiments, the planarization process may include a combination of CMP and/or etch-back processes, for example. The planarization process may remove the lower substrate 12L (see FIG. 4), the bonded layer 18 (see FIG. 4), and unpatterned portions of the semiconductor layer 20. The planarization process may further expose the semiconductor strips 20′ and the STI regions 32.

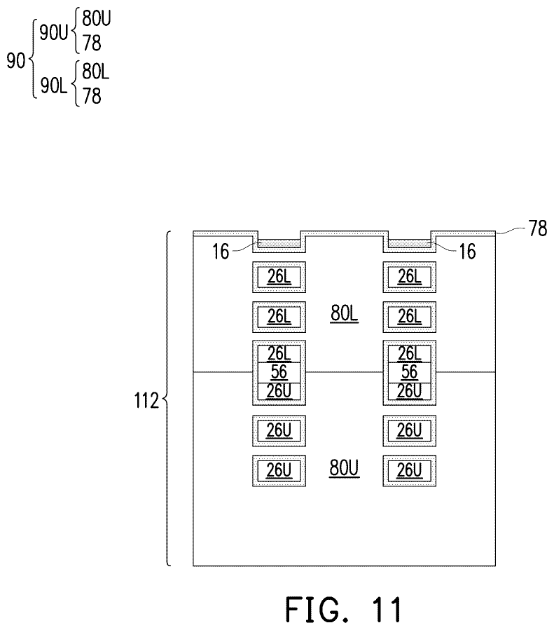

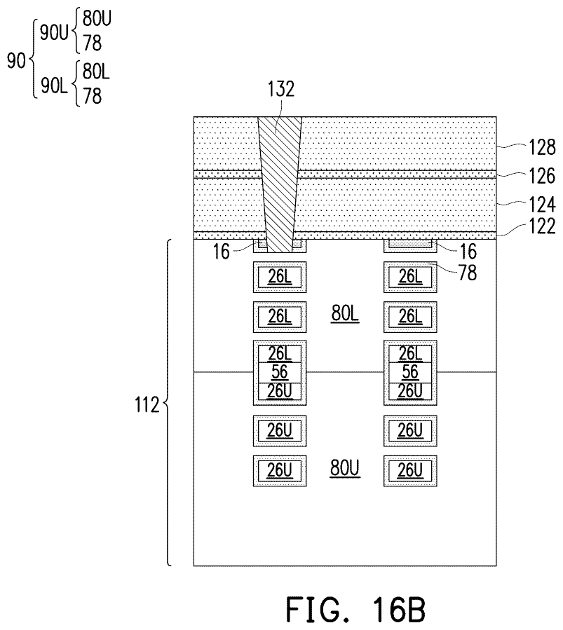

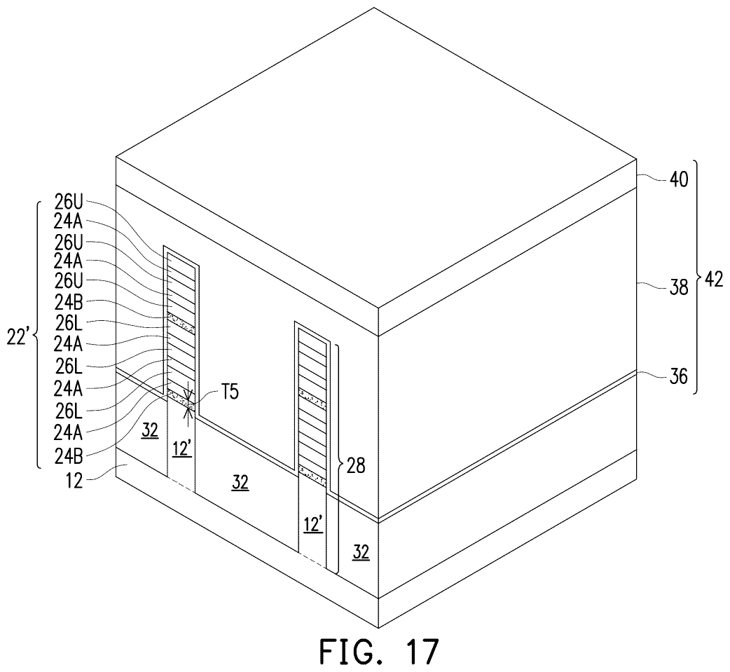

In FIG. 11, one or more etching processes are performed to remove the semiconductor strips 20′ and the STI regions 32. Removing the semiconductor layer 20 and the semiconductor strips 20′ advantageously improves electrical performance by improving isolation between subsequently formed backside gate contacts and/or backside source/drain contacts. For example, by removing the semiconductor layer 20 and the semiconductor strips 20′, concerns regarding backside contact shorting through the semiconductor layer 20/semiconductor strips 20′ may be addressed. Further, STI regions 32 may be removed so that an isolation layer may be blanketed over the backside of the device layer 112. Providing a blanket isolation layer may provide improved film quality by removing the topography (and resulting interfaces) of the STI regions 32. The semiconductor strips 20′ and the STI regions 32 may be removed by any suitable etching process(es) and in any order. In some embodiments, the semiconductor strips 20′ are removed by a wet etching process(es) while the STI regions 32 are removed by dry etching process(es). Removing the semiconductor strips 20′ and the STI regions 32 exposes the gate dielectric layers 78 and the ESL 16 in some embodiments. Optionally, in some embodiments, removing the semiconductor strips 20′ may partially recess the lower source/drain regions 62L below the ESL 16 and/or below a back surface of the lower gate stacks 90L (see FIG. 16A).

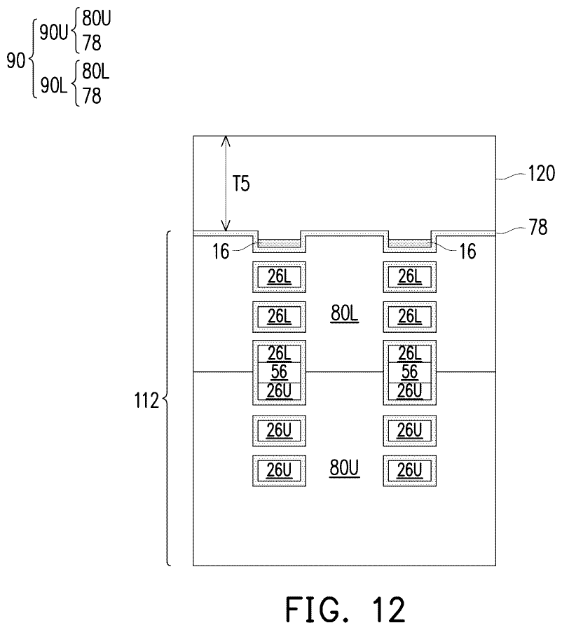

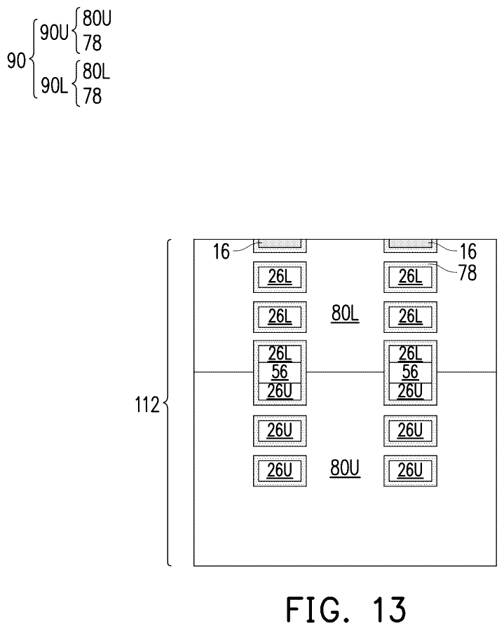

In FIG. 12, a sacrificial layer 120 is deposited over the backside of the device layer 112. The sacrificial layer 120 may comprise an insulating material, such an oxide, or the like that is deposited by any suitable process, such as, PVD, CVD, ALD, or the like. The sacrificial layer 120 may be deposited to improve loading and uniformity control in a subsequent planarization process (see FIG. 13). For example, the sacrificial layer 120 may cover topography and provide a uniform pattern density, thereby reducing the overall burden on the subsequent planarization process and improving planarization results. In some embodiments, the sacrificial layer 120 has a thickness T5 in a range of 30 nm to 50 nm, which has been observed to sufficiently improve the subsequent planarization process.

In FIG. 13, a planarization process (e.g., a CMP process, or the like) is performed, removing the bulk of the sacrificial layer 120 and planarizing a backside of the device layer 112. The planarization process may remove the gate dielectric layer 78 over the backside of the gate stacks 90 and expose the ESL 16. After the planarization process, later surfaces (e.g., backside surfaces) of the ESL 16 and the lower gate electrodes 80L may be substantially level (within process variation). In some embodiments, remaining portions of the sacrificial layer 120 after the planarization process may be removed by a cleaning process, for example.

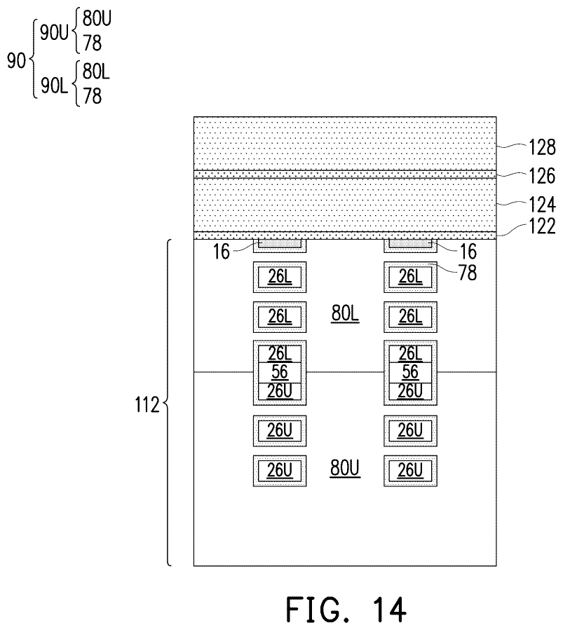

In FIG. 14, a backside ESL 122, a first backside ILD 124, a backside ESL 126, and a second backside ILD 128 are sequentially deposited over the backside of the lower gate electrode 80L and the ESL 16. The backside ESLs 122 and 126 may be formed using similar materials and processes as the front side ESL 104 described above, and the first and second backside ILDs 124 and 128 may be formed using similar materials and processes as the third ILD 106 described above. In some embodiments, the backside ESL 122 may further extend along sidewalls of the ESL 16 to cover a backside of the lower source/drain regions 62L (see FIG. 16A).

In some embodiments, between depositing the first backside ILD 124 and depositing the backside ESL 126, backside source/drain contacts 134 and metal-semiconductor alloy regions 136 (also referred to as silicide regions 136) are formed (see FIG. 16A). The backside source/drain contacts 134 and the metal-semiconductor alloy regions 136 may be formed using similar materials and processes as the source/drain contacts 96 and the metal-semiconductor alloy regions 94, respectively, described above. The backside source/drain contacts 134 may extend through the first backside ILD 124 and the backside ESL 122 to electrically couple to the backside of the bottom source/drain regions 62L. The backside ESL 122 may provide end point control for etching openings that are later filled to form the backside source/drain contacts 134.

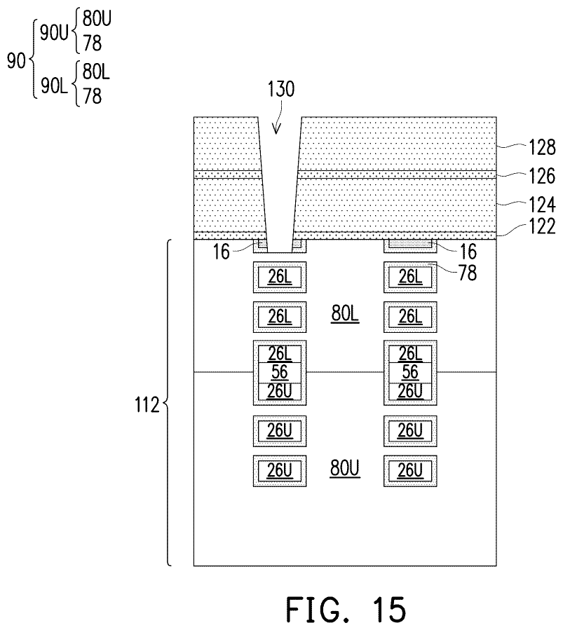

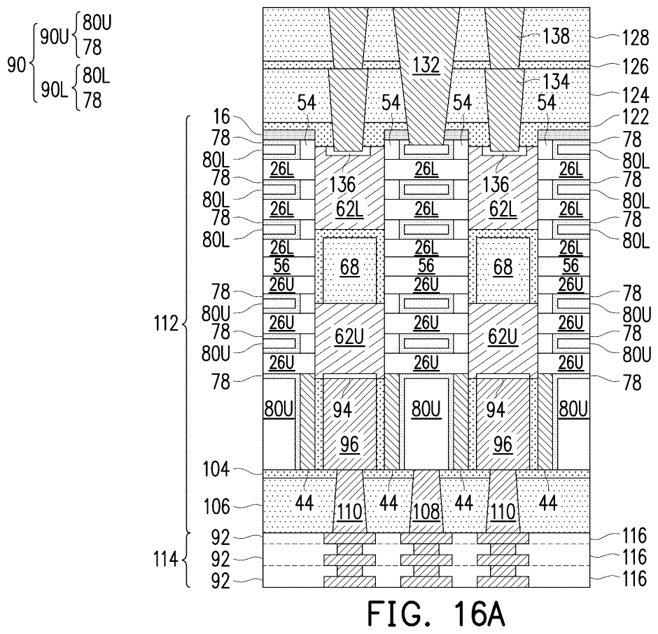

In FIG. 15, backside gate contact openings 130 are patterned through the second backside ILD 128, the backside ESL 126, the first backside ILD 124, the backside ESL 122, the gate ESL 16, and the gate dielectric 78 to expose the lower gate electrode 80L. Patterning the backside gate contact openings 130 may be achieved by a combination of lithography and etching process(es). In particular, etching the gate ESL 16 may use an etchant that selectively etches the gate ESL at a faster rate than surrounding features of the lower nanostructure-FET (e.g., the lower gate electrode 80L and/or the nanostructures 26). For example, the gate ESL 16 may be etched in a dry etching process using a chemical etchant that comprises NF₃, BCl₃, or the like.

The backside gate contact openings 130 may overlap and be laterally aligned with the nanostructures 26, which provide the channel regions of the upper nanostructure-FETs and the lower nanostructure-FETs in the device layer 112. The gate ESL 16 is made of a suitable material and is sufficiently thick to allow the opening 130 to be patterned with precise end-point control. For example, the gate ESL 16 is made of a high-k material (e.g., hafnium oxide) and is at least 3 nm thick in various embodiments. As a result, the backside gate contact openings 130 can directly overlap the nanostructures 26 without damaging the nanostructures 26 (e.g., by over etching). The backside ESL 122 is also included to further improve the end-point control of etching the backside gate contact openings 130.

Because the gate ESL 16 allows the backside gate contact openings 130 to directly overlap the nanostructures 26, the locations overlapped by channel regions (the nanostructures 26) no longer need to be avoided when forming backside gate contacts, allowing for improved routing flexibility. Further, because the nanostructures 26 can be made with larger widths W1 for improved device speed. For example, between 14.4% to 19% device speed improvements have been observed in embodiment devices by increasing the widths of the channel regions. In some embodiments the width W1 is greater than 34 nm, such as in a range of 16 nm to 80 nm, thereby achieving improved device performance. As a result, various embodiments allow for improved process integration, increased routing flexibility, and increased device performance (e.g., speed).

In FIGS. 16A and 16B, backside gate contacts 132 and backside source/drain vias 138 are formed to contact the lower gate electrodes 80L and the source/drain contacts 134, respectively. Specifically, the backside gate contacts 132 may be formed in the backside gate contact openings 130 and overlap the nanostructures 26. As an example to form the backside gate contacts 132, a liner (not separately illustrated), such as a diffusion barrier layer, an adhesion layer, or the like, and a conductive material are formed in the backside gate contact openings 130. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the second backside ILD 128. The remaining liner and conductive material form the backside gate contacts 132 in the backside gate contact openings 130. The backside source/drain vias 138 may be formed of a similar material and process as the source/drain vias 110 described above. The backside gate contacts 132 and the backside source/drain vias 138 may be formed in distinct processes, or may be formed in the same process. Although shown as being formed in the same cross-section, it should be appreciated that each of the backside gate contacts 132 and the backside source/drain vias 138 may be formed in different cross-sections, which may avoid shorting of the contacts.

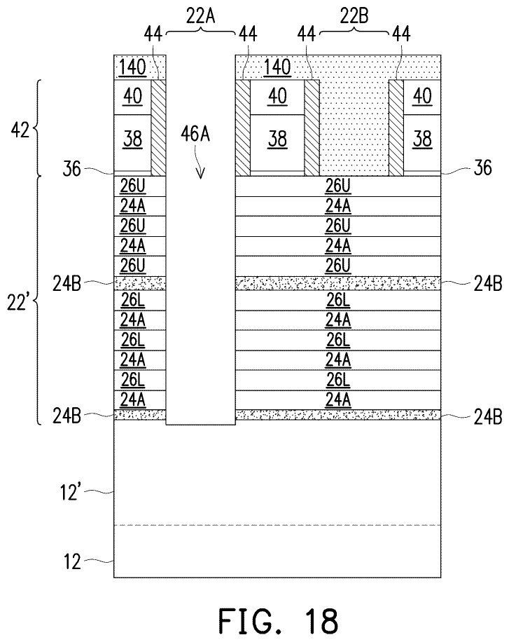

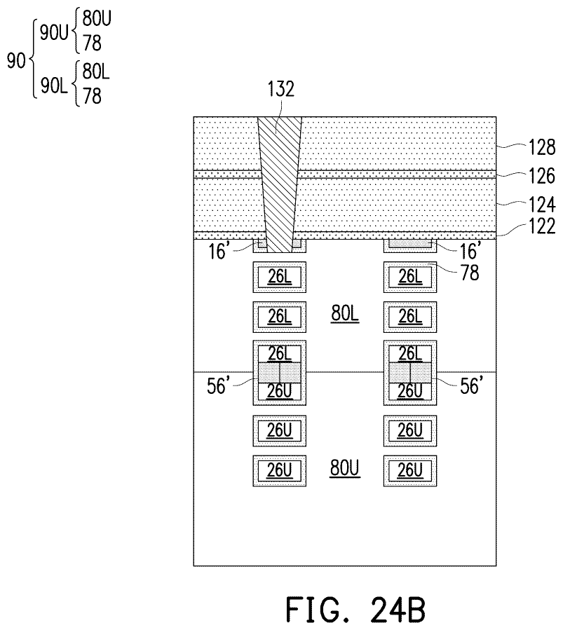

FIGS. 17 through 24B illustrate the cross-sectional views of intermediate stages in the formation of stacking transistors (as schematically represented in FIG. 1) in accordance with some embodiments. In FIGS. 17 through 24B, gate ESLs 16 may be formed without the bonding processes described above (see FIGS. 2A, 2B, and 3). FIG. 17 illustrates a perspective view similar to FIG. 1. FIGS. 18, 19, 20, 21, 22, 23, and 24A illustrate cross-sectional views along a similar cross-section as reference cross-section A-A′ in FIG. 1. FIG. 24B illustrates cross-sectional views along a similar cross-section as reference cross-section B-B′ in FIG. 1. In FIGS. 17 through 24B, like reference numerals indicate like elements formed by like processes as described above in FIGS. 2A through 16B unless otherwise indicated.

FIG. 17 illustrates a perspective view of a semiconductor substrate 12, which may be made of like materials as the semiconductor substrates 12L and 12U described above. Semiconductor strips 28 are formed extending upwards from the semiconductor substrate 12. Each of semiconductor strips 28 includes semiconductor strip 12′ (patterned portions of the semiconductor substrate 12) and a multi-layer stack 22′ of nanostructures. Specifically, the multi-layer stack 22′ includes dummy nanostructures 24A, dummy nanostructures 24B, lower semiconductor nanostructures 26L, and upper semiconductor nanostructures 26U. The semiconductor substrate 12 may also be referred to as a semiconductor layer.

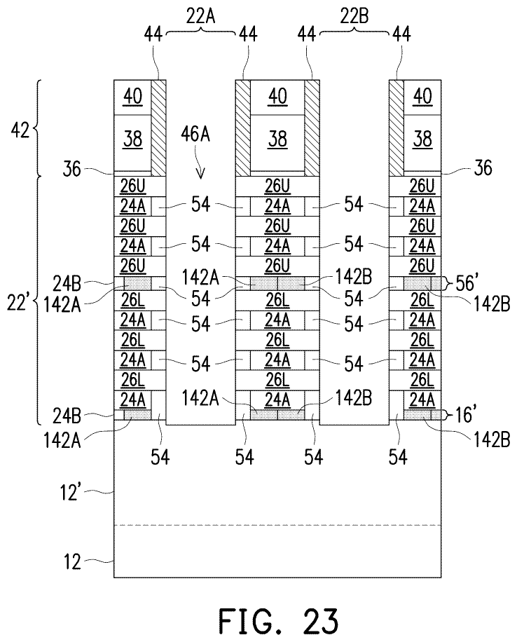

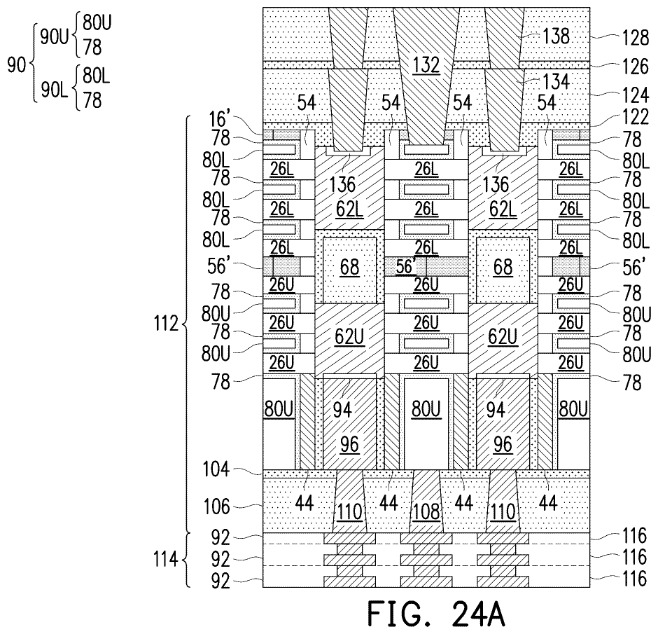

The multi-layer stack 22′ may be made of like materials and like processes as the multi-layer stack 22 with an additional dummy nanostructure 24B included as a bottom layer of the multi-layer stack 22. For example, the additional dummy nanostructure 24B may be a bottommost layer of the multi-layer stack 22′ that is disposed between upper nanostructures of the multi-layer stack 22′ and the underlying semiconductor strip 12′. In subsequent process steps the bottom nanostructure 24B may be replaced with a high-k material to provide a gate ESL (e.g., gate ESL 16, see FIG. 23). The bottom nanostructure 24B may be formed by forming a dummy nanostructure layer (of a similar material/process as the dummy nanostructure layer 14C described above) over the semiconductor substrate 12 and then patterning the dummy nanostructure layer as part of forming the multi-layer stack 22′. Because the bottom nanostructure 24B will be subsequently replaced with a high-k material to form the backside gate ESL, a thickness T5 of the bottom nanostructure 24B may be at least 3 nm. In this manner, the resulting gate ESL is at least 3 nm thick, which advantageously allows the gate ESL to sufficiently protect the underlying nanostructures 26 during backside gate contact formation.

As also illustrated by FIG. 17, STI regions 32 may be formed between the semiconductor strips 12′, and dummy gate stacks 42 (including dummy dielectric layer 36, dummy gate layer 38, and mask layer 40) are formed over and along sidewalls of the multi-layer stacks 22′. The STI regions 32 and the dummy gate stacks 42 may be formed of like materials and like processes as described above. After the dummy gate stacks 42 are patterned, gate spacers 44 (see FIG. 18) may be formed on sidewalls of the dummy gate stacks 42 of materials and processes similar to those described above.

In FIG. 18, a mask layer 140 is deposited and patterned over the dummy gate stacks 42 and the multi-layer stack 22′. The mask layer 140 may be deposited between adjacent dummy gate stacks 42 by a spin-on process, for example. In some embodiments, the mask layer 140 is a photosensitive layer, such as a bottom anti-reflective coating (BARC) layer. The mask layer 140 may be patterned by lithography processes to expose first regions 22A of the multi-layer stack 22′ while masking second regions 22B of the multi-layer stack 22′. Each of the first regions 22A and the second regions 22B are disposed between adjacent ones of the dummy gate stacks 42, and the first regions 22A and the second regions 22B may be alternatingly arranged over the semiconductor substrate 12 where each of the second regions 22B is disposed between adjacent ones of the first regions 22A.

Then, first source/drain recesses 46A are formed in the first regions 22A of the multi-layer stacks 22′. The first source/drain recesses 46A are formed through etching, and may extend through the multi-layer stacks 22′ and into the semiconductor strips 12′. The bottom surfaces of the first source/drain recesses 46A may be at a level above, below, or level with the top surfaces of the isolation regions 32. In the etching processes, the mask layer 140, the gate spacers 44, and the dummy gate stacks 42 mask some portions of the semiconductor strips 28. The etching may include a single etch process or multiple etch processes. Timed etch processes may be used to stop the etching of the first source/drain recesses 46A upon first source/drain recesses 46A reaching a desired depth. After the first source/drain recesses 46A are patterned, the mask layer 140 may be removed by an acceptable process, such as an ashing process.

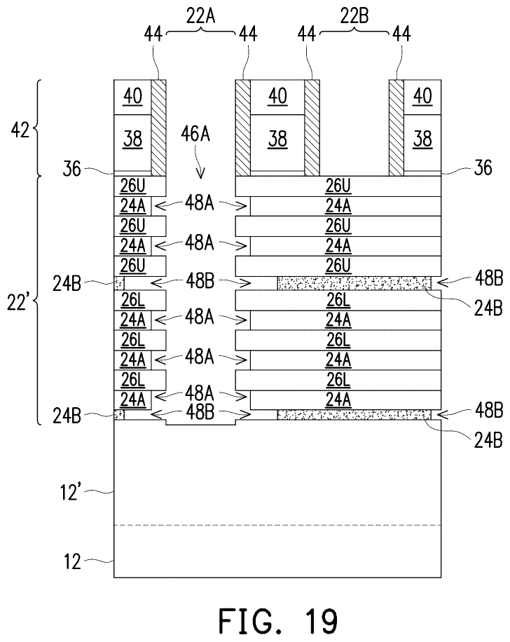

In FIG. 19, a lateral etching process is performed that laterally etches the dummy nanostructures 24A and the dummy nanostructures 24B through the first source/drain recesses 46A. The lateral etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be laterally etched and recessed a greater amount than the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. The lateral etching process recesses the dummy nanostructures 24A to form first recesses 48A, and the lateral etching process recesses the dummy nanostructures 24B to form second recesses 48B that have a larger lateral width than the first recesses 48A. In some embodiments, the lateral etching process removes about 50% of a lateral width of the dummy nanostructures 24A. Although sidewalls of the dummy nanostructures 24A are illustrated as being straight after the etching, the sidewalls may be concave or convex.

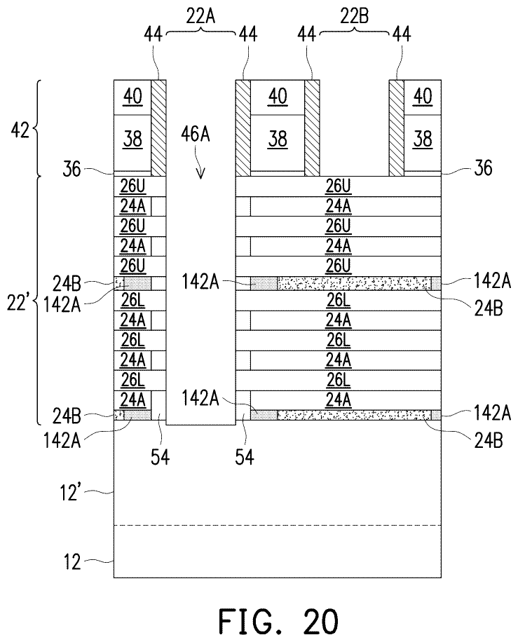

In FIG. 20, inner spacers 54 are formed in the first recesses 48A, and a high-k material 142A and inner spacers 54 are formed in the second recesses 48B. Forming the high-k material 142A includes conformally depositing the high-k material 142A material in the first source/drain recesses 46A, in the first recesses 48A, and in the second recesses 48B on sidewalls of the dummy nanostructures 24B and then etching the high-k material. The high-k material may be any suitable material for protecting the nanostructures 26 during backside gate contact formation as well as provide sufficient isolation between upper and lower nanostructures 26U and 26L. For example, the high-k material 142A may be hafnium oxide, or the like, and the high-k material 142A may have a k-value of at least 15. As such, the high-k material 142A may be selectively etched in subsequent processes to form the backside gate contact. The high-k material 142A may be formed by a deposition process, such as ALD, CVD, or the like. The etching of the high-k material 142A may be anisotropic or isotropic. The high-k material 142A, when etched, has portions remaining in the sidewalls of the dummy nanostructures 24B while other portions of the high-k material 142A may be removed. The etching of the high-k material 142A may further recess the high-k material 142A on sidewalls of the dummy nanostructures 24B beyond sidewalls of the nanostructures 26 such that the nanostructures 26 overhang remaining portions of the high-k material 142A after etching.

After the high-k material 142A is deposited and etched, inner spacers 54 are formed on exposed sidewalls of the dummy nanostructures 24A and the high-k material 142A. The inner spacers 54 may be formed of a similar material and of similar processes as described above. The inner spacers 54 may be used to prevent shorting between subsequently formed gate stacks and subsequently formed source/drain regions.

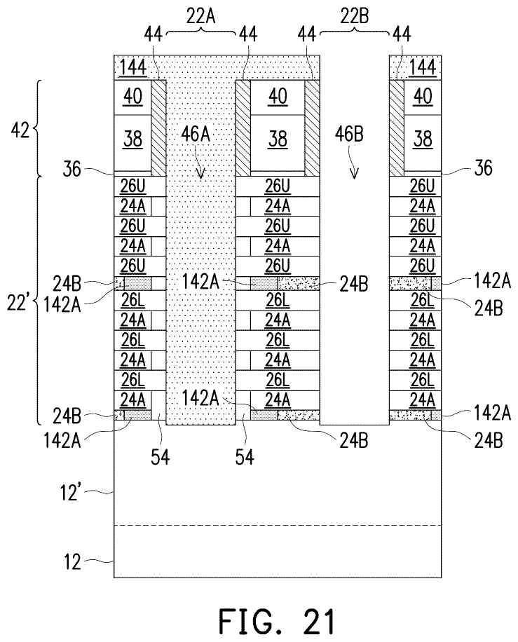

In FIG. 21, a mask layer 144 is deposited and patterned over the dummy gate stacks 42 and the multi-layer stack 22′. The mask layer 144 may be deposited between adjacent dummy gate stacks 42 and in the first source/drain regions 46A by a spin-on process, for example. In some embodiments, the mask layer 144 is a photosensitive layer, such as a BARC layer. The mask layer 144 may be patterned by lithography processes to expose the second regions 22B of the multi-layer stack 22′ while masking the first regions 22A of the multi-layer stack 22′.

Then, second source/drain recesses 46B are formed in second regions 22B of the multi-layer stack 22′. The second source/drain recesses 46B are formed through etching, and may extend through the multi-layer stacks 22′ and into the semiconductor strips 12′. The bottom surfaces of the second source/drain recesses 46B may be at a same level as bottom surfaces of the first source/drain recesses 46A (within process variations), and the mask layer 144, the gate spacers 44, and the dummy gate stacks 42 mask some portions of the semiconductor strips 28 during the etching. The etching may include a single etch process or multiple etch processes. Timed etch processes may be used to stop the etching of the second source/drain recesses 46B upon second source/drain recesses 46B reaching a desired depth.

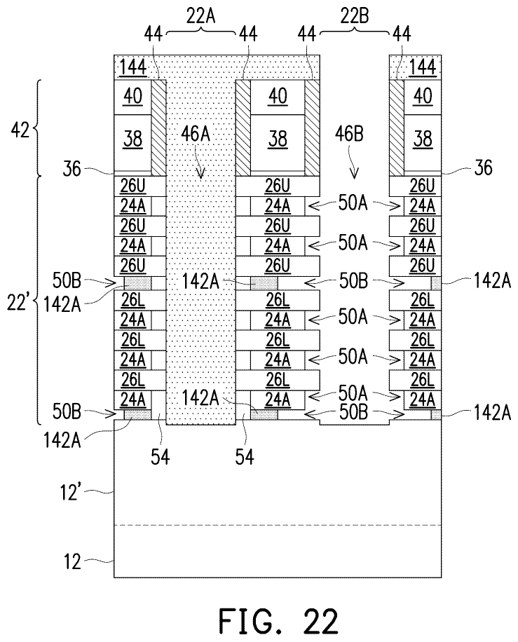

In FIG. 22, a lateral etching process is performed that laterally etches the dummy nanostructures 24A and removes remaining portions of the dummy nanostructures 24B through the second source/drain recesses 46B. The lateral etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, remaining portions of the dummy nanostructures 24B may be fully removed without removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. The lateral etching process recesses the dummy nanostructures 24A to form third recesses 50A, and the lateral etching process removes the dummy nanostructures 24B to form fourth recesses 50B. The fourth recesses 50B expose the high-k material 142A and have a larger lateral width than the third recesses 50A. Although sidewalls of the dummy nanostructures 24A are illustrated as being straight after the etching, the sidewalls may be concave or convex. Further, the mask 144 may mask the first source/drain recesses 46A during the lateral etching process of FIG. 22.

In FIG. 23, additional inner spacers 54 are formed in the third recesses 50A, and a high-k material 142B and inner spacers 54 are formed in the fourth recesses 50B. Forming the high-k material 142B includes conformally depositing the high-k material 142B in the second source/drain recesses 46B, in the third recesses 50A, and in the fourth recesses 50B on sidewalls of the high-k material 142A and then etching the high-k material 142B. The high-k material 142B may be any suitable material for protecting the nanostructures 26 during backside gate contact formation as well as providing isolation between the upper and lower nanostructures 26U and 26L. For example, the high-k material 142B may have a same material composition as the high-k material 142A. In some embodiments, an interface may be disposed at a location where the high-k materials 142A and 142B touch. The high-k material 142B may be formed by a deposition process, such as ALD, CVD, or the like. The etching of the high-k material 142B may be anisotropic or isotropic. The high-k material 142B, when etched, has portions remaining in the sidewalls of the high-k material 142A while other portions of the high-k material 142B may be removed. The etching of the high-k material 142B may further recess the high-k material 142B on sidewalls of the high-k material 142A beyond sidewalls of the nanostructures 26 such that the nanostructures 26 overhang remaining portions of the high-k material 142B after etching.

After the high-k material 142B is deposited and etched, inner spacers 54 are formed on exposed sidewalls of the dummy nanostructures 24A and the high-k material 142B. The inner spacers 54 may be formed of a similar material and of similar processes as described above. The inner spacers 54 may be used to prevent shorting between subsequently formed gate stacks and subsequently formed source/drain regions. Subsequently, the mask 144 may be removed by an acceptable process, such as ashing.

In various embodiments, the high-k materials 142A/142B provide a backside gate ESL 16′ and provide a dielectric isolation layer 56′. Specifically, bottom ones of the high-k materials 142A/142B provide the backside gate ESL 16′, which allows for a backside gate contact (e.g., backside gate contact 132, see FIGS. 16A, 16B, 24A, and 24B) to be formed at a location that overlaps the nanostructures 26. In this manner, the locations overlapped by channel regions (the nanostructures 26) no longer need to be avoided when forming backside gate contacts, allowing for improved routing flexibility. Further, because the nanostructures 26 can be made with larger widths W1 for improved device speed. As a result, various embodiments allow for improved process integration, increased routing flexibility, and increased device performance (e.g., speed). The gate ESL 16′ has a thickness of at least 3 nm to provide sufficient etching control during subsequent backside gate contact formation steps. Further, the ESL 16′ may include an internal, vertical interface between a first portion of the ESL 16′ (the high-k material 142A) and a second portion of the ESL 16′ (the high-k material 142B).

The top ones of the high-k materials 142A/142B provide dielectric isolation layers 56′ to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs. In the embodiments of FIGS. 17 through 24B, the dielectric isolation layers 56′ have a same material composition as the gate ESL 16′. In contrast, the embodiments of FIGS. 2A through 16B also include dielectric isolation layers 56 between the upper and lower semiconductor nanostructures 26U and 26L, but the dielectric isolation layers 56 have a different material composition than the gate ESL 16.

Subsequently, additional processing is performed to form source/drain regions, gate stacks, source/drain contacts, and gate contacts of the stacking transistors to arrive at the device of FIGS. 24A and 24B. The additional processing may be similar to those described above in FIGS. 7 through 16B where like reference numerals indicate like elements formed by like processes and detailed descriptions of these processes are not repeated herein for brevity. As illustrated by FIGS. 24A and 24B, backside gate contacts 132 are formed that electrically connect to a backside of lower gate stacks 90L. The backside gate contacts 132 overlap the nanostructures 26, which are protected by the gate ESL 16′ during the formation of the backside gate contacts 132. In particular, forming the backside contacts 132 may include etching openings through the gate ESL 16 using an etchant that selectively etches the gate ESL at a faster rate than surrounding features of the lower nanostructure-FET (e.g., the lower gate electrode 80L and/or the nanostructures 26) for improved etch end-point control.

In various embodiments, a backside gate ESL allows for backside gate contacts to be formed to a lower gate stack of a stacking transistor at a location where the backside gate contacts are overlapped by the channel regions of the stacking transistor without damaging the channel regions during the backside gate contact formation process. As a result, the locations overlapped by channel regions no longer need to be avoided when forming the backside gate contacts, allowing for improved routing flexibility. Further, because channel regions are able to directly overlap the backside gate contacts, channel regions can have larger widths for improved device speed. As a result, various embodiments allow for improved process integration, increased routing flexibility, and increased device performance.

In accordance with some embodiments, a semiconductor device includes a plurality of first nanostructures, the plurality of first nanostructures extending between first source/drain regions; a plurality of second nanostructures over the plurality of first nanostructures, the plurality of second nanostructure extending between second source/drain regions; a first gate stack around the plurality of first nanostructures; a second gate stack over the first gate stack and disposed around the plurality of second nanostructures; a backside gate etch stop layer (ESL) on a backside of the first gate stack, wherein the plurality of first nanostructures overlaps the backside gate ESL; and a backside gate contact electrically coupled to the first gate stack, wherein the backside gate contact extends through the backside gate ESL to a backside of the first gate stack. In some embodiments, the backside gate ESL is made of a high-k dielectric material. In some embodiments, the backside gate ESL comprises hafnium oxide. In some embodiments, the first gate stack comprises a gate dielectric and a gate electrode over the gate dielectric, and wherein the backside gate contact extends through the gate dielectric to contact the gate electrode. In some embodiments, a lateral surface of the backside gate ESL is level with a backside surface of the gate electrode. In some embodiments, the semiconductor device further includes a dielectric isolation layer between the plurality of first nanostructures and the plurality of second nanostructures, wherein the dielectric isolation layer has a same material composition as the backside gate ESL. In some embodiments, the backside gate ESL comprises an interface between a first portion of the backside gate ESL and a second portion of the backside gate ESL. In some embodiments, the semiconductor device further includes an inner spacer between the first gate stack and the first source/drain regions, wherein the inner spacer is further disposed on a sidewall of the backside gate ESL. In some embodiments, the semiconductor device further includes a dielectric isolation layer between the plurality of first nanostructures and the plurality of second nanostructures, wherein the dielectric isolation layer has a different material composition than the backside gate ESL. In some embodiments, a thickness of the backside gate ESL is at least 3 nm.

In accordance with some embodiments, a semiconductor device includes a device layer comprising: a first transistor comprising a first gate stack, wherein the first gate stack comprises a first gate dielectric and a first gate electrode; and a second transistor vertically stacked with the first transistor. The semiconductor device further includes a first interconnect structure on a front side of the device layer; a gate etch stop layer (ESL) on a backside of the device layer, wherein the gate ESL comprises a high-k dielectric material; and a gate contact on the backside of the device layer, wherein the gate contact extends through the gate ESL and the first gate dielectric to contact the first gate electrode. In some embodiments, the semiconductor device further includes an additional etch stop layer on the backside of the device layer, wherein the gate contact extends through the additional etch stop layer, and wherein the additional etch stop layer has a different material composition than the gate ESL. In some embodiments, the gate contact overlaps channel regions of the first transistor. In some embodiments, the first gate dielectric extends along sidewalls of the gate ESL.

In accordance with some embodiments, a method includes forming a first transistor and a second transistor over a semiconductor layer. The first transistor and the second transistor are vertically stacked; and wherein a backside gate etch stop layer (ESL) is disposed between a backside of a first gate structure of the first transistor and the semiconductor layer. The method further includes removing the semiconductor layer to expose the backside gate etch stop layer; depositing a backside interlayer dielectric (ILD) over the backside gate ESL; patterning an opening through the backside ILD and the backside gate ESL to expose the first gate structure; and forming a backside gate contact in the opening, wherein the backside gate contact extends through the backside gate ESL to electrically connect to the first gate structure. In some embodiments, the method further includes forming a multi-layer stack over a first semiconductor substrate, the multi-layer stack comprising a first semiconductor material alternatingly arranged with a second semiconductor material; depositing a high-k dielectric layer over the multi-layer stack; bonding a second semiconductor substrate over the multi-layer stack; thinning the first semiconductor substrate; patterning the multi-layer stack, wherein patterning the multi-layer stack comprises forming semiconductor nanostructures from the first semiconductor material and dummy nanostructures from the second semiconductor material, and wherein forming the first transistor comprises replacing the dummy nanostructures with the first gate structure; and patterning the high-k dielectric layer to form the backside gate ESL. In some embodiments, the method further includes forming the semiconductor layer over the high-k dielectric layer, wherein the second semiconductor substrate is directly bonded to the semiconductor layer by dielectric to dielectric bonding. In some embodiments, the method further includes forming a dummy semiconductor material over the semiconductor layer; forming a multi-layer stack over a dummy semiconductor material, the multi-layer stack comprising a first semiconductor material alternatingly arranged with a second semiconductor material; patterning the multi-layer stack and the dummy semiconductor material, wherein patterning the multi-layer stack and the dummy semiconductor material comprises forming a first dummy nanostructure from the dummy semiconductor material, forming semiconductor nanostructures from the first semiconductor material, and forming second dummy nanostructures from the second semiconductor material, and wherein forming the first transistor comprises replacing the second dummy nanostructures with the first gate structure; and replacing the first dummy nanostructure with a high-k material to form the backside gate ESL. In some embodiments, the method further includes after removing the semiconductor layer, depositing an additional backside ESL over the backside gate ESL, wherein the backside ILD is deposited over the additional backside ESL, and wherein patterning the opening further comprises patterning the opening through additional backside ESL. In some embodiments, the backside gate contact overlaps first nanostructures of the first transistor and second nanostructures of the second transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of first nanostructures overlapping a plurality of second nanostructures, the first plurality of nanostructures extending between first source/drain regions in a first cross-sectional view, the second plurality of nanostructures extending between second source/drain regions in the first cross-sectional view;
a first gate stack around the plurality of first nanostructures;
a second gate stack overlapping the first gate stack and disposed around the plurality of second nanostructures;
a first inner spacer on a first sidewall of the first gate stack;
a second inner spacer on a second sidewall of the first gate stack, wherein the first inner spacer and the second inner spacer each contact a bottom surface of the plurality of first nanostructures; and
an etch stop layer (ESL) contacting the first inner spacer and the second inner spacer, wherein a first sidewall of the ESL is aligned with a sidewall of the first inner spacer in the first cross-sectional view, wherein a second sidewall of the ESL is aligned with a sidewall of the second inner spacer in the first cross-sectional view, and wherein the first sidewall of the ESL is opposite the second sidewall of the ESL.

2. The semiconductor device of claim 1, wherein the ESL further contacts a bottom surface of the first gate stack.

3. The semiconductor device of claim 1 further comprising a gate contact extending through the ESL to contact a gate electrode of the first gate stack.

4. The semiconductor device of claim 1, wherein the ESL comprises a high-k dielectric material.

5. The semiconductor device of claim 1, wherein the first gate stack comprises a gate dielectric and a gate electrode over the gate dielectric, and wherein the gate dielectric extends along sidewalls of the ESL in a second cross-sectional view that is perpendicular to the first cross-sectional view.

6. The semiconductor device of claim 1, wherein the ESL is disposed between the sidewall of the first inner spacer and the sidewall of the second inner spacer in the first cross-sectional view.

7. The semiconductor device of claim 1, wherein the ESL contacts a bottom surface of the first inner spacer and a bottom surface of the second inner spacer in the first cross-sectional view.

8. The semiconductor device of claim 1 further comprising a dielectric isolation layer between the plurality of first nanostructures and the plurality of second nanostructures.

9. The semiconductor device of claim 8, wherein the dielectric isolation layer has a different material composition than the ESL.

10. The semiconductor device of claim 8, wherein the dielectric isolation layer has a same material composition as the ESL.

11. The semiconductor device of claim 1, wherein a thickness of the ESL is at least 3 nm.

12. A semiconductor device comprising:
a device layer comprising:
a first transistor comprising a first gate stack around first nanostructures, wherein the first gate stack comprises a first gate dielectric and a first gate electrode; and
a second transistor vertically stacked with the first transistor;
a first interconnect structure on a front side of the device layer;
a gate etch stop layer (ESL) on a backside of the first gate dielectric, wherein the first gate dielectric extends along sidewalls of the gate ESL in a first cross-sectional view; and
a second interconnect structure on a backside of the device layer and comprising a gate contact extending through the gate ESL and the first gate dielectric to the first gate electrode, wherein the first nanostructures and the gate contact are vertically stacked in the first cross-sectional view.

13. The semiconductor device of claim 12 further comprising an additional etch stop layer on the backside of the device layer, wherein the gate contact extends through the additional etch stop layer, and wherein the additional etch stop layer has a different material composition than the gate ESL.

14. The semiconductor device of claim 13, wherein the additional etch stop layer contacts a lateral surface of the first gate electrode.

15. The semiconductor device of claim 13, wherein the additional etch stop layer contacts a sidewall of the gate ESL in a second cross-sectional view that is perpendicular to the first cross-sectional view.

16. The semiconductor device of claim 13 further comprising an insulating spacer extending continuously from a sidewall of the additional etch stop layer to a sidewall of the gate ESL in a second cross-sectional view that is perpendicular to the first cross-sectional view.

17. A semiconductor device comprising:
a device layer comprising a first transistor, the first transistor comprising:
first nanostructures adjoining a first source/drain region and a second source/drain region in a first cross-sectional view; and
a first gate stack around the first nanostructures, the first gate stack comprising a first gate dielectric and a first gate electrode;
a first interconnect structure on a front side of the device layer;
a second interconnect structure on a backside of the device layer, the second interconnect structure comprising:
a gate etch stop layer (ESL), wherein the first gate dielectric covers a top surface sidewalls of the gate ESL in a second cross-sectional view, and wherein the gate ESL at least partially covers a bottommost surface of the first gate dielectric in the first cross-sectional view, the second cross-sectional view being perpendicular to the first cross-sectional view; and
a gate contact extending through the gate ESL and the first gate dielectric to the first gate electrode.

18. The semiconductor device of claim 17, wherein a bottom surface of the first gate electrode is level with a bottom surface of the gate ESL in the second cross-sectional view.

19. The semiconductor device of claim 17, wherein the gate ESL extends continuously from the first source/drain region to the second source/drain region in the first cross-sectional view.

20. The semiconductor device of claim 17 further comprising an inner spacer separating the first gate stack from the first source/drain region and further separating the gate ESL from the first source/drain region in the first cross-sectional view.
